(19) United States
(12) Patent Application Publication
(10) Pub. No.: US 2025/0343132 A1
(43) Pub. Date: Nov. 6, 2025

(54) MEMORY DEVICES WITH VIA STRUCTRUES AND METHODS OF MANUFACTURING THEREOF

(71) Applicant: Taiwan Semiconductor Manufacturing Company, Ltd., Hsinchu (TW)

(72) Inventors: Yi-Hsin Nien, Hsinchu (TW); Hidehiro Fujiwara, Hsinchu (TW); Chih-Yu Lin, Hsinchu (TW); Kao-Cheng Lin, Hsinchu (TW); Ying Chih Chen, Hsinchu (TW); Yen-Huei Chen, Hsinchu (TW)

(73) Assignee: Taiwan Semiconductor Manufacturing Company, Ltd., Hsinchu (TW)

(21) Appl. No.: 18/798,980

(22) Filed: Aug. 9, 2024

Related U.S. Application Data
(60) Provisional application No. 63/642,080, filed on May 3, 2024.

(51) Int. Cl. H01L 23/522; H01L 23/528; H10B 10/00

(52) U.S. Cl. CPC H01L 23/5226; H01L 23/528; H01L 23/5283; H10B 10/12

(57) ABSTRACT

A memory device includes a plurality of first memory cells formed in a first area of a substrate, a plurality of first via structures formed in a second area of the substrate, the second area being disposed next to the first area along a first lateral direction, a first one of a plurality of frontside interconnect structures formed on a first side of the substrate, wherein the first frontside interconnect structure is coupled to gate terminals of access transistors of the plurality of first memory cells, and a first one of a plurality of backside interconnect structures formed on a second side of the substrate vertically opposite to the first side, wherein the first backside interconnect structure is coupled to the first frontside interconnect structure through one or more of the plurality of first via structures.

### CROSS-REFERENCE TO RELATED APPLICATION

This application claims priority to and the benefit of U.S. Provisional Application No. 63/642,080, filed May 3, 2024, entitled “Back-Side Global Fly WL on SRAM Array,” which is incorporated herein by reference in its entirety for all purposes.

### BACKGROUND

The semiconductor integrated circuit (IC) industry has experienced exponential growth. As ICs continue to scale down, more and more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device, in accordance with some embodiments.

FIG. 2 illustrates a schematic diagram of an example circuit that can be included in the memory device of FIG. 1, in accordance with some embodiments.

FIG. 3A and FIG. 3B illustrate an example layout associated with an example circuit, in accordance with some embodiments.

FIG. 4 illustrates a schematic diagram of an example circuit that can be included in the memory device of FIG. 1, in accordance with some embodiments.

FIG. 5A and FIG. 5B illustrate an example layout associated with an example circuit, in accordance with some embodiments.

FIG. 6A and FIG. 6B illustrate schematic diagrams of example circuits that can be included in the memory device of FIG. 1, in accordance with some embodiments.

FIG. 7 illustrates a schematic diagram of an example circuit that can be included in the memory device of FIG. 1, in accordance with some embodiments.

FIG. 8 illustrates an example layout associated with an example circuit, in accordance with some embodiments.

FIG. 9 illustrates a flow chart of an example method for forming a memory device.

FIG. 10 illustrates a flow chart of an example method for forming a memory device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, the delay of a word line (WL) is one of factors significantly affecting the overall speed of a memory device (e.g., a Static Random-Access Memory (SRAM)). SRAM devices retain data while power is supplied, providing faster access speeds and better reliability for high-performance applications. However, as semiconductor technology scales down, the poly pitch, the spacing between polysilicon lines, also decreases, which results in narrower WLs with increased resistance and capacitance, which in turn degrades the WL delay and slows down the memory access speed. Furthermore, in a memory device where backside metal lines are used, the backside metal lines cannot be directly connected to the frontside device gate, which requires indirect connections that lead to higher resistance and capacitance while increasing design complexity. The present disclosure can address these challenges by utilizing via structures to implement a backside WL scheme, effectively improving WL delay.

The present disclosure provides various embodiments of a memory device (or an integrated circuit). The memory device can include a memory array formed in a first area of a substrate, a first interconnect structure formed on a first side of the substrate, a second interconnect structure formed on a second side of the substrate, and a via structure formed in a second area of the substrate such that the via structure can couple the first interconnect structure to the second interconnect structure. This can achieve the backside WL scheme while improving the WL delay issues, without significantly impacting a device area.

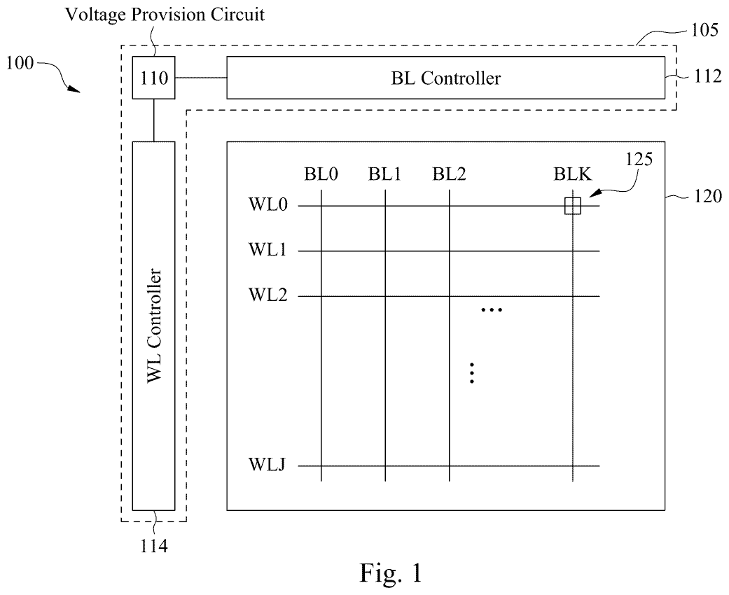

FIG. 1 illustrates a block diagram of an example memory device 100, in accordance with some embodiments. The memory device 100 includes a memory controller 105 and a memory array 120. In one aspect, the memory array 120 includes a plurality of storage circuits or memory cells 125. The memory array 120 further includes word lines WL₀, WL₁ . . . WL_{J}, each extending in a first direction (e.g., X-direction) and bit lines BL₀, BL₁ . . . BL_{K}, each extending in a second direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the second direction (e.g., Y-direction). The bit lines BL, BLB may receive and/or provide differential signals.

Each memory cell 125 may include a volatile memory cell, a non-volatile memory cell, or a combination of them. For example, each memory cell 125 is embodied as a static random access memory (SRAM) cell. However, it should be appreciated that the memory cell 125 can be implemented as any of various other non-volatile memory cells such as, for example, a resistive random access memory (RRAM) cell, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, and a voltage provision circuit 110. The BL controller 112, the WL controller 114, and the voltage provision circuit 110 may be embodied as logic circuits, analog circuits, or a combination of them. In one configuration, the WL controller 114 is a circuit that provides a voltage or current through one or more word lines WLs of the memory array 120, and the BL controller 112 is a circuit that provides or senses a voltage or current through one or more bit lines BLs of the memory array 120. In one configuration, the voltage provision circuit 110 is a circuit that provides a voltage signal to the BL controller 112 and/or the WL controller 114. The BL controller 112 may be coupled to bit lines BLs of the memory array 120, and the WL controller 114 may be coupled to word lines WLs of the memory array 120. In some embodiments, the memory controller 105 includes more, fewer, or different components than shown in FIG. 1.

In various embodiments, the memory array 120 can include a plurality of memory cells 125 formed in a first area of a substrate. The memory array 120 can include a first interconnect structure that is formed on a first side of the substrate and operatively serves as a first portion of a word line for the plurality of memory cells 125. The memory array 120 can include a second interconnect structure that is formed on a second side of the substrate opposite to the first side and operatively serves as a second portion of the word line for the plurality of memory cells 125. The memory array 120 can include one or more via structures that are formed in a second area of the substrate next to the first area along a lateral direction and are configured to couple the first interconnect structure to the second interconnect structure. The first interconnect structure and the second interconnect structure each can extend along the lateral direction to traverse both the first and second areas.

In some embodiments, the memory device 100 can include a plurality of first memory cells 125 formed in a first area of a substrate. The memory device 100 can include a plurality of first via structures formed in a second area of the substrate, the second area being disposed next to the first area along a first lateral direction. The memory device 100 can include a first one of a plurality of frontside interconnect structures formed on a first side of the substrate. The first frontside interconnect structure can be coupled to gate terminals of access transistors of the plurality of first memory cells 125. The memory device 100 can include a first one of a plurality of backside interconnect structures formed on a second side of the substrate vertically opposite to the first side. The first backside interconnect structure can be coupled to the first frontside interconnect structure through one or more of the plurality of first via structures.

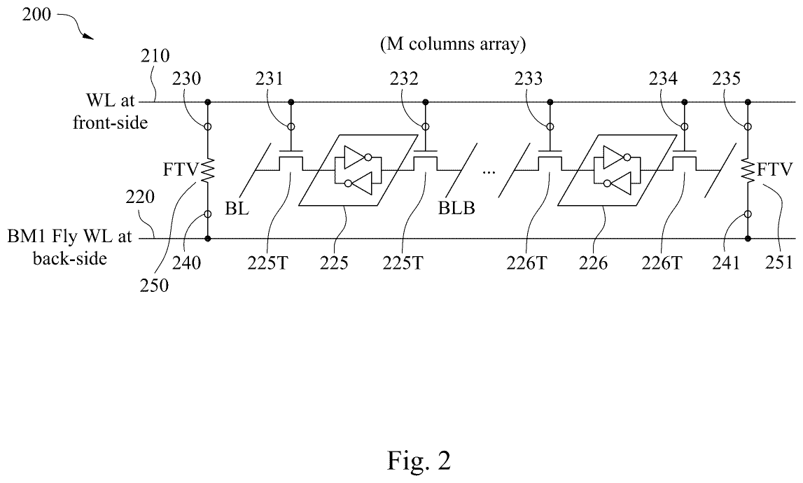

FIG. 2 illustrates a schematic diagram of an example circuit 200 that can be included in the memory device of FIG. 1, in accordance with some embodiments. The circuit 200 can include a plurality of memory cells (e.g., memory cells 225, 226), a first word line 210, a second word line 220, first interconnect structures 230, 231, 232, 233, 234, 235, second interconnect structures 240, 241, one or more via structures 250, and one or more via structures 251. It should be appreciated that the schematic diagram of FIG. 2 is simplified for illustrative purposes, and thus, the circuit 200 can be implemented as any of various other configurations while remaining within the scope of the present disclosure.

The plurality of memory cells may be of the memory array 120. In some embodiments, the plurality of memory cells can be arranged along a row and across a plurality of columns (e.g., M columns) of a memory array. In some embodiments, the plurality of memory cells can be formed in a first area of a substrate. The plurality of memory cells (e.g., the memory cells 225, 226) can include or be coupled with access transistors (e.g., access transistors 225T, 226T). The access transistors 225T, 226T can connect the memory cells 225, 226 with the corresponding bit lines BL/BLB. In some embodiments, the memory cell(s) 225 can include a plurality of first memory cells, and the memory cell(s) 226 can include a plurality of second memory cells. In some embodiments, each of the plurality of memory cells (e.g., the memory cell(s) 225, the memory cell(s) 226, etc.) can include a static random access memory (SRAM) cell.

The first word line 210 and the second word line 220 may be of the memory array 120. In some embodiments, the first word line 210 can be a word line at a frontside. In some embodiments, the second word line 220 can be a word line at a backside. The first word line 210 and the second word line 220 can be connected in various manners. In some embodiments, the first word line 210 and the second word line 220 can be connected through the first interconnect structure 230, the second interconnect structure 240, and the one or more via structures 250. In some embodiments, the one or more via structures 250 may be a feedthrough via structure. In some embodiments, the first interconnect structure 230 can be formed on a first side (e.g., the frontside) of the substrate. For example, the first interconnect structure 230 can be a frontside interconnect structure. In some embodiments, the first interconnect structure 230 can be configured to operatively serve as a portion of the first word line 210 for the memory cell(s) 225. In some embodiments, the second interconnect structure 240 can be formed on a second side (e.g., the backside) of the substrate opposite to the first side. For example, the second interconnect structure 240 can be a backside interconnect structure. In some embodiments, the second interconnect structure 240 can be configured to operatively serve as a portion of the word line 220 for the memory cell(s) 225.

In some embodiments, the circuit 200 can include a plurality of frontside interconnect structures (e.g., the first interconnect structure 230, interconnect structures 231, 232, 233, 234 etc.). The interconnect structures 231, 232, 233, 234 can be formed on the frontside of the substrate. In some embodiments, the interconnect structures 231, 232 can be coupled to gate terminals of the memory cell(s) 225. For example, the interconnect structures 231, 232 can be coupled to gate terminals of the access transistors 225T of the memory cell(s) 225. In some embodiments, the interconnect structures 231, 232 can be configured to operatively serve as a portion of the first word line 210 for the memory cell(s) 225, while coupled to the memory cell(s) 225 through the gate terminals of the access transistors 225T. In some embodiments, the circuit 200 can include a plurality of backside interconnect structures (e.g., the second interconnect structure 240, interconnect structure 241, etc.). As shown, the interconnect structures 240, 241 can be formed on the backside of the substrate vertically opposite to the frontside. In some embodiments, the interconnect structures 233, 234 can be coupled to gate terminals of the memory cell(s) 226. For example, the interconnect structures 233, 234 can be coupled to gate terminals of the access transistors 226T of the memory cell(s) 226. In some embodiments, the interconnect structures 233, 234 can be configured to operatively serve as a portion of the first word line 210 for the memory cell(s) 226, while coupled to the memory cell(s) 226 through the gate terminals of the access transistors 226T.

The one or more via structures 250 can be formed in a second area of the substrate. For example, the second area can be next to the first area (e.g., where the plurality of memory cells can be formed). In some embodiments, as shown, the one or more via structures 250 can be configured to couple the first interconnect structure 230 (e.g., the frontside interconnect structure) to the second interconnect structure 240 (e.g., the backside interconnect structure).

In some embodiments, the first word line 210 and the second word line 220 can be connected through the first interconnect structure 235, the second interconnect structure 241, and the one or more via structures 251. In some embodiments, the first interconnect structure 235 can be formed on the first side (e.g., the frontside) of the substrate. For example, the first interconnect structure 235 can be a frontside interconnect structure. In some embodiments, the first interconnect structure 235 can be configured to operatively serve as a portion of the first word line 210 for the memory cell(s) 226. In some embodiments, the second interconnect structure 241 can be formed on the second side (e.g., the backside) of the substrate opposite to the first side. For example, the second interconnect structure 241 can be a backside interconnect structure. In some embodiments, the second interconnect structure 241 can be configured to operatively serve as a portion of the word line 220 for the memory cell(s) 226.

In some embodiments, the circuit 200 can include a plurality of frontside interconnect structures (e.g., the first interconnect structure 235, interconnect structures 233, 234, etc.) associated with a second memory cell (e.g., the memory cell(s) 226). The interconnect structures 233, 234 can be formed on the frontside of the substrate. In some embodiments, the interconnect structures 233, 234 can be coupled to gate terminals of the memory cell(s) 226. For example, the interconnect structures 233, 234 can be coupled to gate terminals of the access transistors 226T of the memory cell(s) 226. In some embodiments, the interconnect structures 233, 234 can be configured to operatively serve as a portion of the first word line 210 for the memory cell(s) 226, while coupled to the memory cell(s) 226 through the gate terminals of the access transistors 226T. In some embodiments, the circuit 200 can include a plurality of backside interconnect structures (e.g., the second interconnect structure 240, interconnect structure 241, etc.). As shown, the interconnect structures 240, 241 can be formed on the backside of the substrate vertically opposite to the frontside.

The one or more via structures 251 can be formed in the second area of the substrate. For example, the second area can be next to the first area (e.g., where the plurality of memory cells can be formed). In some embodiments, as shown, the one or more via structures 251 can be configured to couple the first interconnect structure 235 (e.g., the frontside interconnect structure) to the second interconnect structure 241 (e.g., the backside interconnect structure). In some embodiments, the one or more via structures 251 can be formed in an opposite portion (e.g., opposite to the one or more via structures 250 with respect to the memory cells 225, 226, etc.) of the second area of the substrate.

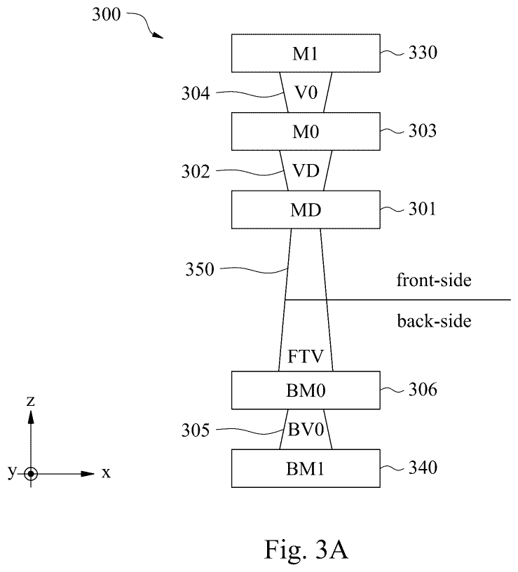

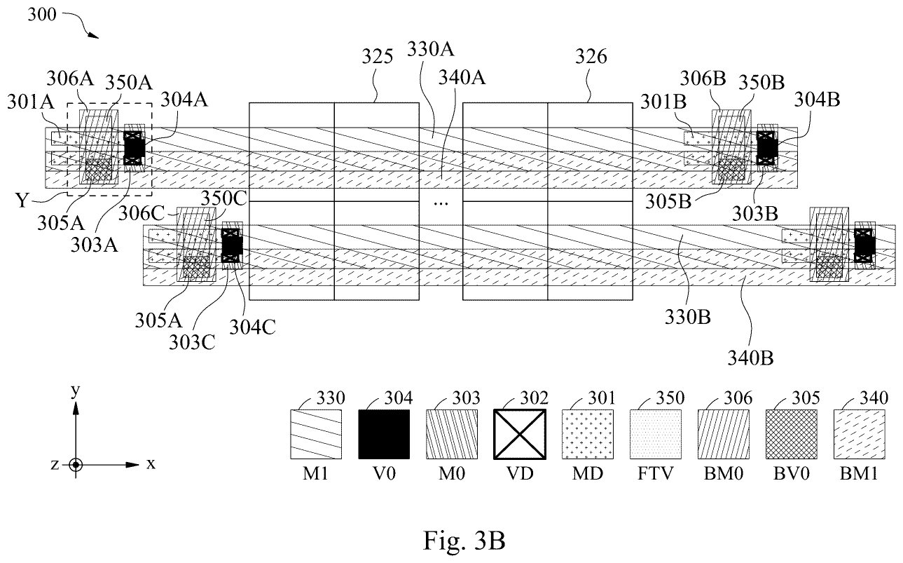

FIG. 3A and FIG. 3B illustrate an example layout 300 associated with an example circuit, in accordance with some embodiments. More specifically, shown in FIG. 3A is a cross-sectional view of the layout 300, particularly of a portion Y in FIG. 3B. Shown in FIG. 3B is a top-down view of the layout 300. In some embodiments, the layout 300 may be associated with the circuit 200. The layout 300 shown in FIG. 3A and FIG. 3B is a non-limiting example and is simplified for illustrative purposes. It should be appreciated that the layout 300 can be implemented as any of various other configurations while remaining within the scope of the present disclosure.

Referring to FIG. 3A, in some embodiments, on a frontside of a substrate, the circuit can include an active region (e.g., a number of transistors, gate structures, source/drain structures, etc.) and at least a portion of a via structure 350. Over the frontside, the circuit can include a number of source/drain interconnect structures (sometimes referred to as MDs 301), some of which are coupled with gate via structures (sometimes referred to as VDs 302) formed thereupon and the via structure 350. Over the gate structures of the transistors in the active region, the circuit can include a number of gate via structures (sometimes referred to as VGs) (not shown).

The VD 302 can couple the MD 301 to a first metal line in the first (e.g., bottommost) frontside metallization layer (sometimes referred to as an M0 track 303). Over the first metal line (e.g., the M0 track 303) (and various other metal lines in the bottommost frontside metallization layer), the circuit can include a number of via structures (sometimes referred to as VOs 304), to couple the first metal line (e.g., the M0 track 303) to corresponding one or more metal lines in the next frontside metallization layer farther away from the substrate (sometimes referred to as M1 tracks 330). Further, over the M1 tracks 330 (and various other metal lines in the same frontside metallization layer), the circuit can include a number of via structures (not shown) to couple the M1 tracks 302 to corresponding one or more metal lines in the next frontside metallization layer farther away from the substrate. Although two frontside metallization layers are shown, it should be understood that the circuit can include any number of frontside metallization layers. The metal tracks formed across such frontside metallization layers can be configured to electrically couple different components of the circuit (so as to route signals and/or deliver power), in accordance with various embodiments.

Referring to FIG. 3A, on a backside of the substrate, the circuit can include a number of backside via structures (sometimes referred to as BVs), that can couple the source/drain structure and gate structure of the transistors in the active region to a number of metal lines in the first (e.g., topmost) backside metallization layer (sometimes referred to as BM0 tracks 306).

In some embodiments, on the backside of the substrate, the circuit can include at least a portion of the via structure 350. In some embodiments, over the BM0 tracks 306, the circuit can include a number of via structures (sometimes referred to as BV0s 305), that can couple the BM0 tracks 306 to a number of metal lines in the next backside metallization layer farther away from the substrate (e.g., BM1 tracks 340). Still further, over the BM1 tracks 340, the circuit can include a number of via structures (sometimes referred to as BV1s) (not shown), that can couple the BM1 tracks 340 to a number of metal lines in the next backside metallization layer farther away from the substrate (sometimes referred to as BM2 tracks) (not shown).

Shown in FIG. 3B is the layout 300 in a top-down view. In a first area of the substrate, the circuit associated with the layout 300 (e.g., the circuit 200) can include a plurality of memory cells (e.g., the first memory cells 325, the second memory cells 326, etc.). The circuit can include a plurality of via structures in a second area (e.g., including the portion Y) of the substrate. The second area can be next to the first area along a lateral direction (e.g., the x-axis as shown in FIG. 3B).

In some embodiments, the circuit can include the plurality of memory cells arranged along a row and across a plurality of columns of a memory array formed in the first area. In some embodiments, the second memory cells 326 can be aligned with the first memory cells 325 along the x-axis. In some embodiments, although not shown, the second memory cells 326 can be aligned with the first memory cells 325 along the y-axis.

In some embodiments, the circuit can include via structures and interconnect structures (e.g., the BM0 306, M0 303, etc.) formed in various portions of the second area. For example, as shown in FIG. 3B, the circuit can include a first set of via structures (e.g., via structures 304A, 305A, etc.) and a first set of interconnect structures (e.g., the BM0 306A, M0 303A, etc.) in a first portion of the second area; and a second set of via structures (e.g., via structures 304B, 305B, etc.) and a second set of interconnect structures (e.g., the BM0 306B, M0 303B, etc.) in a second portion of the second area. In some embodiments, as shown in FIG. 3B, the set of via structures and the set of interconnect structures can be arrayed along the x-axis and/or the y-axis. In some embodiments, as shown in FIG. 3B, the set of via structures (e.g., the via structures 304B, 305B, 304C, 304C, etc.) can be displaced from another set (e.g., the via structures 304A, 305A, etc.) of via structures in both of the x-axis and the y-axis. In some embodiments, as shown in FIG. 3B, the set of interconnect structures (e.g., the BM0 306A, M0 303A, etc.) can be displaced from another set (e.g., the BM0 306B, the M0 303B, BM0 306C, the M0 303C, etc.) of interconnect structures in both of the x-axis and the y-axis. In some embodiments, the circuit can include a plurality of M1 tracks (e.g., the M1 track 330A, M1 track 330B, etc.) arranged along the y-axis. As shown in FIG. 3B, the M1 track 330B can be displaced from the M1 track 330A in both of the x-axis and the y-axis. In some embodiments, the circuit can include a plurality of BM1 tracks (e.g., the BM1 track 340A, BM1 track 340B, etc.) arranged along the y-axis. As shown in FIG. 3B, the BM1 track 340B can be displaced from the BM1 track 340A in both of the x-axis and the y-axis.

In some embodiments, the M1 track 330 can extend along the x-axis (e.g., shown as the M1 tracks 330A, 330B in FIG. 3B). In some embodiments, the M1 track 330 can traverse the first memory cell(s) 325, the second memory cell(s) 326, etc. In some embodiments, the M0 track 303 can extend along the y-axis (e.g., shown as the M0 tracks 303A, 303B in FIG. 3B). In some embodiments, the M0 track 303 can traverse the M1 track 330, the BM1 track 340, etc. In some embodiments, the MD 301 can extend along the x-axis (e.g., shown as MD 301A, MD 301B in FIG. 3B). In some embodiments, the MD 301 can traverse the M0 track 303, the BM0 track 306, etc. In some embodiments, the BM0 track 306 can extend along the y-axis (e.g., shown as the BM0 tracks 306A, 306B in FIG. 3B). In some embodiments, the BM0 track 306 can traverse the M1 track 330, the BM1 track 340, etc. In some embodiments, the BM1 track 340 can extend along the x-axis (e.g., shown as the BM1 tracks 340A, 340B in FIG. 3B). In some embodiments, the BM1 track 340 can traverse the first memory cell(s) 325, the second memory cell(s) 326, etc.

In some embodiments, the via structures (e.g., the V0 304, VD 302, the via structure 350, BV0 305, etc.) can extend along the z-axis to connect at least one of the M1 330, M0 303, MD 301, BM0 306, and BM1 340 with another.

In some embodiments, one or more of the via structures can each extend through the substrate (e.g., through the z-axis). For example, the via structure 350 can extend through the substrate to connect a first interconnect structure in the frontside to a second interconnect structure in the backside. In some embodiments, one or more of the via structures can be configured to couple the first interconnect structure to the second interconnect structure. For example, as shown in FIG. 3A, the via structures (e.g., the via structure 350, VD 302, V0 304, BV0 305, etc.) can couple the first interconnect structure (which can be or part of the M1 track 330) and the second interconnect structure (which can be or part of the BM1 track 340). In some embodiments, the via structure can each extend through the substrate to connect the first side (e.g., the frontside) to the second side (e.g., the backside) of the substrate.

Referring to FIG. 3B, in some embodiments, the circuit associated with the layout 300 (e.g., the circuit 200) can include a first interconnect structure formed on a first side (e.g., the frontside) of the substrate. In some embodiments, the first interconnect structure can be or part of a frontside interconnect structure. For example, the first interconnect structure can be or part of the M1 tracks 330. In some embodiments, the first interconnect structure can be configured to operatively serve as a first portion of a word line (e.g., a word line at the frontside) for the plurality of memory cells (e.g., the first memory cells 325, the second memory cells 326, etc.). In some embodiments, the circuit can include a second interconnect structure formed on a second side (e.g., the backside) of the substrate opposite to the first side. In some embodiments, the second interconnect structure can be or part of a backside interconnect structure. For example, the second interconnect structure can be or part of the BM1 tracks 340. In some embodiments, the second interconnect structure can be configured to operatively serve as a second portion of a word line (e.g., a word line at the backside) for the plurality of memory cells (e.g., the first memory cells 325, the second memory cells 326, etc.).

In some embodiments, the circuit associated with the layout 300 (e.g., the circuit 200) can include a plurality of first interconnect structures formed on the first side (e.g., the frontside) of the substrate. For example, the circuit can include a first interconnect structure that can be or part of the M0 track 303. In some embodiments, the circuit can include a plurality of backside interconnect structures formed on the second side (e.g., the backside) of the substrate vertically opposite to the first side. For example, the circuit can include a second interconnect structure that can be or part of the BM0 track 306. In some embodiments, at least one first interconnect structure (e.g., the frontside interconnect structure) can be coupled to gate terminals of access transistors of the plurality of memory cells (e.g., the first memory cells 325, the second memory cells 326, etc.). In some embodiments, at least one second interconnect structure (e.g., the backside interconnect structure) can be coupled to at least one first interconnect structure through one or more of the plurality of via structures (e.g., the via structure 350).

In some embodiments, referring to FIG. 3B, the circuit associated with the layout 300 (e.g., the circuit 200) can include the first interconnect structure (which can be or part of the M1 track 330) and the second interconnect structure (which can be or part of the BM1 track 340) each extending along the lateral direction (e.g., the x-axis) to traverse both the first and second areas.

In some embodiments, referring to FIG. 3A, the circuit associated with the layout 300 (e.g., the circuit 200) can include a plurality of first interconnect structures (e.g., frontside interconnect structures). For example, the circuit can include a second one of the first interconnect structures (e.g., a second frontside interconnect structure) vertically disposed between the substrate and a first one of the first frontside interconnect structures. For example, the first one of the first interconnect structures can be or part of the M1 tracks 330, and the second one of the first interconnect structures can be or part of the MD 301, such that the second one of the first interconnect structures can be vertically disposed between the substrate and the first one of the first interconnect structures. In some embodiments, the circuit associated with the layout 300 (e.g., the circuit 200) can include a plurality of second interconnect structures (e.g., backside interconnect structures). For example, the circuit can include a second one of the second interconnect structures vertically disposed between the substrate and a first one of the second interconnect structures. For example, the first one of the second interconnect structures can be or part of the BM1 tracks 340, and the second one of the second interconnect structures can be or part of the BM0 track 306, such that the second one of the second interconnect structures can be vertically disposed between the substrate and the first one of the second interconnect structures. In some embodiments, as shown in FIG. 3A, the via structure 350 can be in direct contact with the second one of the first interconnect structures (e.g., the MD 301) and the second one of the second interconnect structures (e.g., the BM0 306).

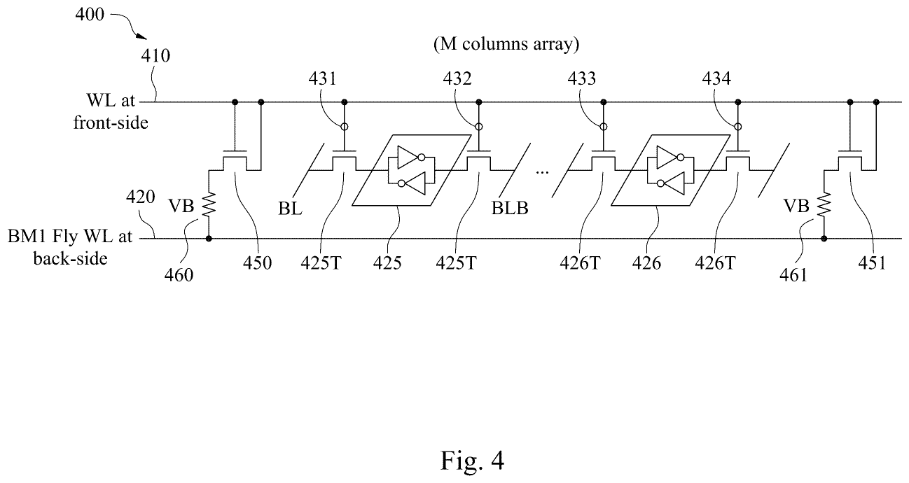

FIG. 4 illustrates a schematic diagram of an example circuit 400 that can be included in the memory device of FIG. 1, in accordance with some embodiments. The circuit 400 can include a plurality of memory cells (e.g., the memory cells 425, 426), a first word line 410, a second word line 420, first interconnect structures 431, 432, 433, 434, transistors 450, 451, one or more via structures 460, and one or more via structures 461. It should be appreciated that the schematic diagram of FIG. 4 is simplified for illustrative purposes, and thus, the circuit 400 can be implemented as any of various other configurations while remaining within the scope of the present disclosure.

In some embodiments, the circuit 400 can be substantially similar to or incorporate features of the circuit 200. In some embodiments, the circuit 400 can alternatively include the transistors 450, 451 and the via structures 460, 461, as opposed to the circuit 200 including the via structures 250, 251 and the interconnect structures 230, 240, 235, 241.

In some embodiments, at least one of the transistors 450, 451 can be formed in the second area of the substrate. For example, the transistors 450, 451 can be formed in the second area next to the first area where the memory cells 425, 426 are formed. In some embodiments, as shown in FIG. 4, a gate terminal and a first source/drain terminal of the transistors 450, 451 can be coupled to the first interconnect structure (which can be a portion of the word line 410), and a second source/drain terminal of the transistors 450, 451 can be coupled to the second interconnect structure (which can be a portion of the word line 420) through the one or more via structures 460, 461.

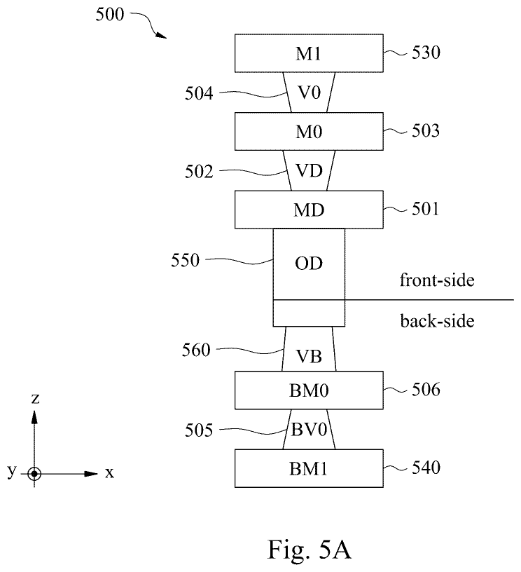

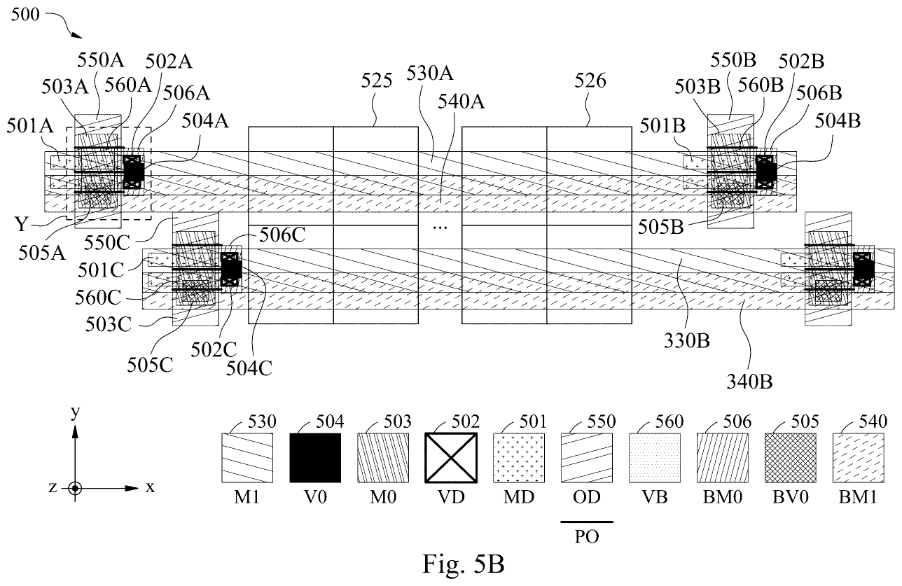

FIG. 5A and FIG. 5B illustrate an example layout 500 associated with an example circuit, in accordance with some embodiments. More specifically, shown in FIG. 5A is a cross-sectional view of the layout 500, particularly of a portion Y in FIG. 5B. Shown in FIG. 5B is a top-down view of the layout 500. In some embodiments, the layout 500 may be associated with the circuit 400. The layout 500 shown in FIG. 5A and FIG. 5B is a non-limiting example and is simplified for illustrative purposes. It should be appreciated that the layout 500 can be implemented as any of various other configurations while remaining within the scope of the present disclosure.

Referring to FIG. 5A, in some embodiments, on a frontside of a substrate, the circuit can include an active region (e.g., a number of transistors, gate structures, source/drain structures, etc.) in a first area and at least a portion of a dissipation element 550 (e.g., a dummy element to form a transistor therein) in a second area next to the first area. Over the frontside, the circuit can include a number of source/drain interconnect structures (sometimes referred to as MDs 500R), some of which are coupled with gate via structures (sometimes referred to as VDs 502) formed thereupon and the dissipation element 550. Over the gate structures of the transistors in the active region of the first area, the circuit can include a number of gate via structures (sometimes referred to as VGs) (not shown).

The VD 502 can couple the MD 501 to a first metal line in the first (e.g., bottommost) frontside metallization layer (sometimes referred to as an M0 track 503). Over the first metal line (e.g., the M0 track 503) (and various other metal lines in the bottommost frontside metallization layer), the circuit can include a number of via structures (sometimes referred to as VOs 504), to couple the first metal line (e.g., the M0 track 503) to corresponding one or more metal lines in the next frontside metallization layer farther away from the substrate (sometimes referred to as M1 tracks 530). Further, over the M1 tracks 530 (and various other metal lines in the same frontside metallization layer), the circuit can include a number of via structures (not shown) to couple the M1 tracks 502 to corresponding one or more metal lines in the next frontside metallization layer farther away from the substrate. Although two frontside metallization layers are shown, it should be understood that the circuit can include any number of frontside metallization layers. The metal tracks formed across such frontside metallization layers can be configured to electrically couple different components of the circuit (so as to route signals and/or deliver power), in accordance with various embodiments.

Referring to FIG. 5A, on a backside of the substrate, the circuit can include a number of backside via structures (sometimes referred to as BVs), that can couple the source/drain structure and gate structure of the transistors in the active region of the first area to a number of metal lines in the first (e.g., topmost) backside metallization layer (sometimes referred to as BM0 tracks 506). In some embodiments, on the backside of the substrate, in the second area next to the first area, the circuit can include the via structure 560. In some embodiments, over the BM0 tracks 506, the circuit can include a number of via structures (sometimes referred to as BV0s 505), that can couple the BM0 tracks 506 to a number of metal lines in the next backside metallization layer farther away from the substrate (e.g., BM1 tracks 540). Still further, over the BM1 tracks 540, the circuit can include a number of via structures (sometimes referred to as BV1s) (not shown), that can couple the BM1 tracks 540 to a number of metal lines in the next backside metallization layer farther away from the substrate (sometimes referred to as BM2 tracks) (not shown).

As shown, the dissipation element 550 and the via structure 560 can be connected while connecting the M1 track 540 and the BM1 track 540. In some embodiments, a gate terminal and a first source/drain terminal of the transistor (e.g., the transistors 450) in the dissipation element 550 can be coupled to the M1 track 540, and a second source/drain terminal of the transistor in the dissipation element 550 can be coupled to the BM1 track 540 through the one or more via structures (e.g., the via structure 560, the BV0, etc.).

Shown in FIG. 5B is the layout 500 in a top-down view. In a first area of the substrate, the circuit associated with the layout 500 (e.g., the circuit 400) can include a plurality of memory cells (e.g., the first memory cells 525, second memory cells 526, etc.). The circuit can include a plurality of via structures in a second area (e.g., the portion Y) of the substrate. The second area can be next to the first area along a lateral direction (e.g., the x-axis as shown in FIG. 5B).

In some embodiments, the circuit can include the plurality of memory cells arranged along a row and across a plurality of columns of a memory array formed in the first area. In some embodiments, the second memory cells 526 can be aligned with the first memory cells 525 along the x-axis. In some embodiments, although not shown, the second memory cells 526 can be aligned with the first memory cells 525 along the y-axis.

In some embodiments, the circuit can include transistors, via structures and interconnect structures (e.g., the BM0 506, M0 503, etc.) formed in various portions of the second area. For example, as shown in FIG. 5B, the circuit can include a first set of via structures (e.g., via structures 504A, 505A, 560A, etc.), a dissipation element 550A, and a first set of interconnect structures (e.g., the BM0 506A, M0 503A, etc.) in a first portion of the second area; and a second set of via structures (e.g., via structures 504B, 505B, etc.), a dissipation element 550B, and a second set of interconnect structures (e.g., the BM0 506B, M0 503B, etc.) in a second portion of the second area. In some embodiments, as shown in FIG. 5B, the set of via structures, the transistors, and the set of interconnect structures can be arrayed along the x-axis and/or the y-axis. In some embodiments, as shown in FIG. 5B, the set of via structures (e.g., via structures 504B, 505B, 560B, 504C, 505C, 560C, etc.) can be displaced from another set (e.g., via structures 504A, 505A, 560B, etc.) of via structures in both of the x-axis and the y-axis. In some embodiments, as shown in FIG. 5B, the set of interconnect structures (e.g., the BM0 506B, M0 503B, BM0 506C, M0 503C, etc.) can be displaced from another set (e.g., the BM0 506A, M0 503A, etc.) of interconnect structures in both of the x-axis and the y-axis. In some embodiments, the circuit can include a plurality of M1 tracks (e.g., the M1 track 530A, M1 track 530B, etc.) arranged along the y-axis. As shown in FIG. 5B, the M1 track 530B can be displaced from the M1 track 530A in both of the x-axis and the y-axis. In some embodiments, the circuit can include a plurality of BM1 tracks (e.g., the BM1 track 540A, BM1 track 540B, etc.) arranged along the y-axis. As shown in FIG. 5B, the BM1 track 540B can be displaced from the BM1 track 540A in both of the x-axis and the y-axis.

In some embodiments, the M1 track 530 can extend along the x-axis (e.g., shown as the M1 tracks 530A, 530B in FIG. 5B). In some embodiments, the M1 track 530 can traverse the first memory cells 525, the second memory cell 526, etc. In some embodiments, the M0 track 503 can extend along the y-axis (e.g., shown as the M0 tracks 503A, 503B in FIG. 5B). In some embodiments, the M0 track 503 can traverse the M1 track 530, the BM1 track 540, etc. In some embodiments, the MD 501 can extend along the x-axis (e.g., shown as MD 501A, MD 501B in FIG. 5B). In some embodiments, the MD 501 can traverse the M0 track 503, the BM0 track 506, etc. In some embodiments, the BM0 track 506 can extend along the y-axis (e.g., shown as the BM0 tracks 506A, 506B in FIG. 5B). In some embodiments, the BM0 track 506 can traverse the M1 track 530, the BM1 track 540, etc. In some embodiments, the BM1 track 540 can extend along the x-axis (e.g., shown as the BM1 tracks 540A, 540B in FIG. 5B). In some embodiments, the BM1 track 540 can traverse the first memory cells 525, the second memory cell 526, etc.

In some embodiments, the via structures (e.g., the V0 504, the VD 502, the BV0 505, etc.) can extend along the z-axis to connect at least one of the M1 530, M0 503, MD 501, BM0 506, and BM1 540 with another. In some embodiments, the dissipation element 550 can extend along the y-axis (e.g., shown as the dissipation elements 550A, 550B, in FIG. 5B). In some embodiments, the dissipation element 550 can traverse the M1 track 530, BM1 track 540, etc.

In some embodiments, one or more of the via structures and/or transistors can each extend through the substrate (e.g., through the z-axis). For example, the dissipation element 550 and the via structure 560 can extend through the substrate to connect a first interconnect structure in the frontside to a second interconnect structure in the backside. In some embodiments, one or more of the via structures can be configured to couple the first interconnect structure to the second interconnect structure. For example, as shown in FIG. 5A, the transistor formed in the dissipation element 550 and the via structure 560 can couple the first interconnect structure (which can be or part of the M1 track 530) and the second interconnect structure (which can be or part of the BM1 track 540). In some embodiments, the dissipation element 550 and the via structure 560 can each extend through the substrate such that the transistor in the dissipation element 550 and the via structure 560 can connect the first side (e.g., the frontside) to the second side (e.g., the backside) of the substrate. As shown in FIG. 5A, the transistor in the dissipation element 550 and the via structure 560 can connect the first side (e.g., the frontside) to the second side (e.g., the backside) of the substrate.

Referring to FIG. 5B, in some embodiments, the circuit associated with the layout 500 (e.g., the circuit 400) can include a first interconnect structure formed on a first side (e.g., the frontside) of the substrate. In some embodiments, the first interconnect structure can be or part of a frontside interconnect structure. For example, the first interconnect structure can be or part of the M1 tracks 530. In some embodiments, the first interconnect structure can be configured to operatively serve as a first portion of a word line (e.g., a word line at the frontside) for the plurality of memory cells (e.g., the first memory cells 525, second memory cells 526, etc.). In some embodiments, the circuit can include a second interconnect structure formed on a second side (e.g., the backside) of the substrate opposite to the first side. In some embodiments, the second interconnect structure can be or part of a backside interconnect structure. For example, the second interconnect structure can be or part of the BM1 tracks 540. In some embodiments, the second interconnect structure can be configured to operatively serve as a second portion of a word line (e.g., a word line at the backside) for the plurality of memory cells (e.g., the first memory cells 525, second memory cells 526, etc.).

In some embodiments, the circuit associated with the layout 500 (e.g., the circuit 400) can include a plurality of first interconnect structures formed on the first side (e.g., the frontside) of the substrate. For example, the circuit can include a first interconnect structure that can be or part of the M0 track 503. In some embodiments, the circuit can include a plurality of backside interconnect structures formed on the second side (e.g., the backside) of the substrate vertically opposite to the first side. For example, the circuit can include a second interconnect structure that can be or part of the BM0 track 506. In some embodiments, at least one first interconnect structure (e.g., the frontside interconnect structure) can be coupled to gate terminals of access transistors of the plurality of memory cells (e.g., the first memory cells 525, second memory cells 526, etc.). In some embodiments, at least one second interconnect structure (e.g., the backside interconnect structure) can be coupled to at least one first interconnect structure through one or more of the plurality of via structures and transistors (e.g., the transistor in the dissipation element 550 and the via structure 560).

In some embodiments, referring to FIG. 5B, the circuit associated with the layout 500 (e.g., the circuit 400) can include the first interconnect structure (which can be or part of the M1 track 530) and the second interconnect structure (which can be or part of the BM1 track 540) each extending along the lateral direction (e.g., the x-axis) to traverse both the first and second areas.

In some embodiments, referring to FIG. 5A, the circuit associated with the layout 500 (e.g., the circuit 400) can include a plurality of first interconnect structures (e.g., frontside interconnect structures). For example, the circuit can include a second one of the first interconnect structures (e.g., a second frontside interconnect structure) vertically disposed between the substrate and a first one of the first frontside interconnect structures. For example, the first one of the first interconnect structures can be or part of the M1 tracks 530, and the second one of the first interconnect structures can be or part of the MD 501, such that the second one of the first interconnect structures can be vertically disposed between the substrate and the first one of the first interconnect structures. In some embodiments, the circuit associated with the layout 500 (e.g., the circuit 400) can include a plurality of second interconnect structures (e.g., backside interconnect structures). For example, the circuit can include a second one of the second interconnect structures vertically disposed between the substrate and a first one of the second interconnect structures. For example, the first one of the second interconnect structures can be or part of the BM1 tracks 540, and the second one of the second interconnect structures can be or part of the BM0 track 506, such that the second one of the second interconnect structures can be vertically disposed between the substrate and the first one of the second interconnect structures. In some embodiments, as shown in FIG. 5A, the dissipation element 550 and/or the via structure 560 can be in direct contact with the second one of the first interconnect structures (e.g., the MD 401) and the second one of the second interconnect structures (e.g., the BM0 506).

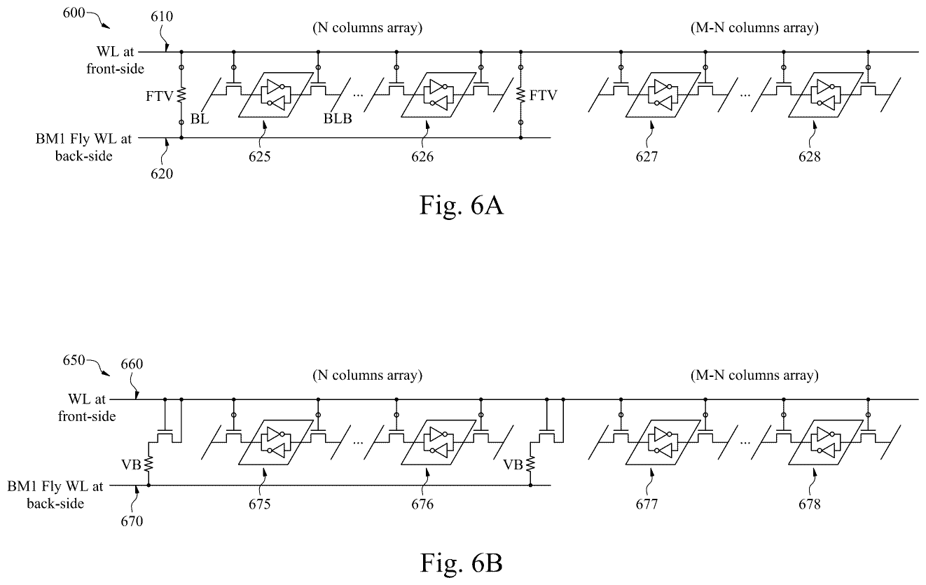

FIG. 6A illustrates a schematic diagram of an example circuit 600 that can be included in the memory device of FIG. 1, in accordance with some embodiments. The circuit 600 can include a plurality of memory cells (e.g., the memory cells 625, 626, 627, 628), a first word line 610, a second word line 620, etc. It should be appreciated that the schematic diagram of FIG. 6A is simplified for illustrative purposes, and thus, the circuit 600 can be implemented as any of various other configurations while remaining within the scope of the present disclosure.

In some embodiments, the circuit 600 can be substantially similar to or incorporate features of the circuit 200. In some embodiments, the circuit 600 can alternatively include the word line 620 connected a portion of columns associated with the plurality of memory cells (e.g., the memory cells 625, 626, etc.) while not connected to another portion of columns associated with the other plurality of memory cells (e.g., the memory cells 627, 628, etc.), as opposed to the circuit 200 including the word line 220 connected to the columns associated with the memory cells (e.g., the memory cells 225, 226, etc.). For example, as shown in FIG. 6A, the circuit 600 can include M columns. The word line 620 can be connected N columns associated with the plurality of memory cells (e.g., the memory cells 625, 626, etc.) while not connected to M-N columns associated with the other plurality of memory cells (e.g., the memory cells 627, 628, etc.). In some embodiments, the memory cells 627, 628 can be connected to the word line 610 without connecting to the word line 620.

FIG. 6B illustrates a schematic diagram of an example circuit 650 that can be included in the memory device of FIG. 1, in accordance with some embodiments. The circuit 650 can include a plurality of memory cells (e.g., the memory cells 675, 676, 677, 678), a first word line 660, a second word line 670. It should be appreciated that the schematic diagram of FIG. 6B is simplified for illustrative purposes, and thus, the circuit 650 can be implemented as any of various other configurations while remaining within the scope of the present disclosure.

In some embodiments, the circuit 650 can be substantially similar to or incorporate features of the circuit 400. In some embodiments, the circuit 650 can alternatively include the word line 670 connected a portion of columns associated with the plurality of memory cells (e.g., the memory cells 675, 676, etc.) while not connected to another portion of columns associated with the other plurality of memory cells (e.g., the memory cells 677, 678, etc.), as opposed to the circuit 400 including the word line 420 connected to the whole memory cells (e.g., the memory cells 425, 426, etc.). For example, as shown in FIG. 6B, the circuit 650 can include M columns. The word line 670 can be connected N columns associated with the plurality of memory cells (e.g., the memory cells 675, 676, etc.) while not connected to M-N columns associated with the other plurality of memory cells (e.g., the memory cells 677, 678, etc.). In some embodiments, the memory cells 677, 678 can be connected to the word line 660 without connecting to the word line 670.

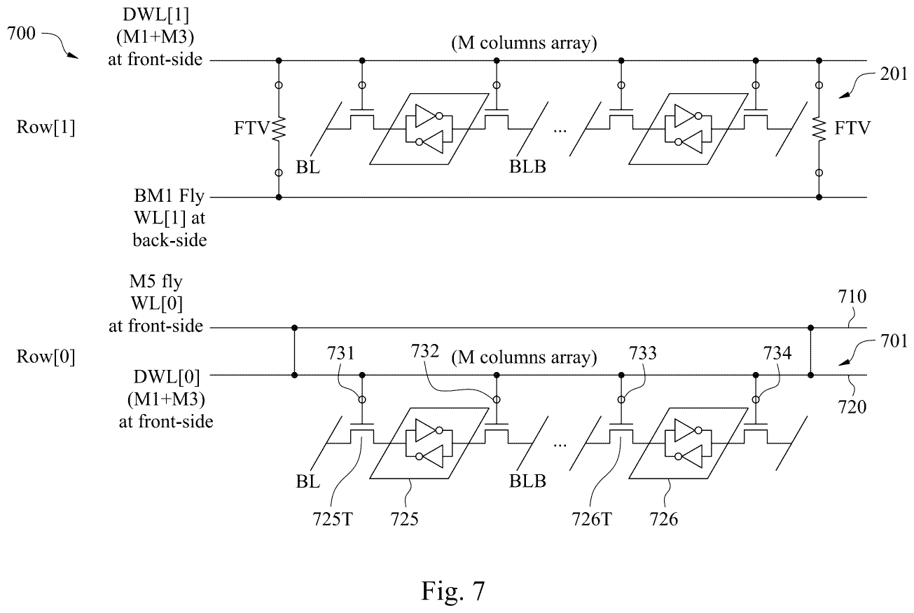

FIG. 7 illustrates a schematic diagram of an example circuit 700 that can be included in the memory device of FIG. 1, in accordance with some embodiments. The circuit 700 can include a row 200R of the circuit 200 and a row 700R of a circuit. The row 700R can include a first word line 710, a second word line 720, a plurality of memory cells (e.g., memory cells 725, 726), interconnect structures 731, 732, 733, 734, etc. It should be appreciated that the schematic diagram of FIG. 7 is simplified for illustrative purposes, and thus, the circuit 700 can be implemented as any of various other configurations while remaining within the scope of the present disclosure.

In some embodiments, the circuit 700 can be substantially similar to or incorporate features of the circuit 200. In some embodiments, the circuit 700 can alternatively include the row 700R, as opposed to the circuit 200 which can include a plurality of rows 200R. In some embodiments, the circuit 700 can include a plurality of rows, which can be any arrangement of the row 200R and the row 700R. For example, the row 200R and the row 700R can be alternately arranged.

The plurality of memory cells may be of the memory array 120. In some embodiments, the plurality of memory cells (e.g., the memory cells 725, 726) can be arranged along a row and across a plurality of columns (e.g., M columns) of a memory array. In some embodiments, the plurality of memory cells can be arranged such that each of the plurality of memory cells can be aligned with a corresponding one of the plurality of memory cells in the row 200R For example, the memory cells 725, 726 can correspond to the memory cells 225, 226, etc.

In some embodiments, the plurality of memory cells (e.g., the memory cells 725, 726) can include or be coupled with access transistors (e.g., access transistors 725T, 726T). The access transistors 725T, 726T can connect the memory cells 725, 726 with the corresponding bit lines BL/BLB. In some embodiments, the memory cell(s) 725 can include a plurality of first memory cells, and the memory cell(s) 726 can include a plurality of second memory cells. In some embodiments, each of the plurality of memory cells (e.g., the memory cell(s) 725, the memory cell(s) 726, etc.) can include a static random access memory (SRAM) cell.

The first word line 710 and the second word line 720 may be of the memory array 120. In some embodiments, the first word line 710 can be a word line associated with a first metallization layer at a frontside. In some embodiments, the second word line 720 can be a word line associated with a second metallization layer at the frontside. For example, the first word line 710 can be associated with one or more of metallization layers formed at a top portion of the frontside. The second word line 720 can be associated with one or more of metallization layers formed at a bottom portion of the frontside. In some embodiments, the row 700R can include the interconnect structures 731, 732, 733, 734, etc. The interconnect structures 731, 732, 733, 734 can be coupled to gate terminals of the memory cells 725, 726. For example, the interconnect structures 731, 732 and the interconnect structures 733, 734 can be coupled to the corresponding gate terminal of the access transistors 725T and 726T, respectively.

In some embodiments, the word line 710 can be connected to a metallization layer (e.g., an M5 track) at a first row (e.g., Row[0] or even rows) of the frontside, while the word line 720 can be connected to one or more metallization layers (e.g., M1 and M3 tracks) at the first row of the frontside. In some embodiments, the word line 210 of the row 200R can be connected to one or more metallization layers (e.g., M1 and M3 tracks) at a second row (e.g., Row[1] or odd rows) of the frontside, while the word line 220 of the row 200R can be connected to a metallization layer (e.g., an M5 track) at the second row of the backside.

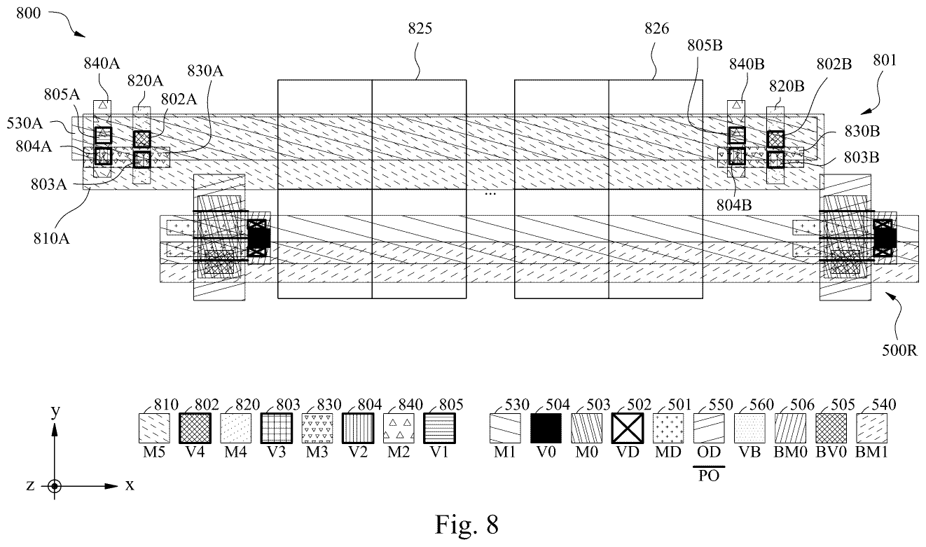

FIG. 8 illustrates an example layout 800 associated with an example circuit, in accordance with some embodiments. More specifically, shown in FIG. 8 is a top-down view of the layout 800. In some embodiments, the layout 800 may be associated with the circuit 700. The layout 800 shown in FIG. 8 is a non-limiting example and is simplified for illustrative purposes. It should be appreciated that the layout 800 can be implemented as any of various other configurations while remaining within the scope of the present disclosure.

In some embodiments, the layout 800 can be substantially similar to or incorporate features of the layout 500. In some embodiments, the layout 800 can alternatively include a row 801, as opposed to the layout 500 which can include a plurality of rows 500R. In some embodiments, the layout 800 can include a plurality of rows, which can be any arrangement of the row 801 and the row 500R. For example, the row 801 and the row 500R can be alternately arranged.

In a first area of the substrate, the circuit associated with the layout 800 (e.g., the circuit 700) can include a plurality of memory cells (e.g., the first memory cells 825, the second memory cells 826, etc.). The circuit can include a plurality of via structures in a second area of the substrate. The second area can be next to the first area along a lateral direction (e.g., the x-axis as shown in FIG. 8).

In some embodiments, the circuit can include the plurality of memory cells arranged along a row and across a plurality of columns of a memory array formed in the first area. In some embodiments, the plurality of memory cells can be formed such that the row 500R and the row 801 traverse the plurality of memory cells.

In some embodiments, the circuit can include via structures (e.g., V1 805, V2 804, V3 803, V4 802, etc.) and inter connect structures (e.g., M5 810, M4 820, M3 830, M2 840, etc.) formed in various portions of the second area. For example, as shown in FIG. 8, the circuit can include a first set of via structures (e.g., V1 805A, V2 804A, V3 803A, V4 802A, etc.) and a first set of interconnect structures (e.g., M5 810A, M4 820A, M3 830A, M2 840A, etc.) in a first portion of the second area; and a second set of via structures (e.g., V1 805B, V2 804B, V3 803B, V4 802B, etc.) and a second set of interconnect structures (e.g., M5 810B, M4 820B, M3 830B, M2 840B, etc.) in a second portion of the second area. In some embodiments, as shown in FIG. 8, the set of via structures and the set of interconnect structures can be arrayed along the x-axis (and/or the y-axis (not shown)). In some embodiments, as shown in FIG. 8, the set of via structures (e.g., V1 805A, V2 804A, V3 803A, V4 802A, etc.) can be displaced from the other set (e.g., via structures 504A, 505A, 560B, etc.) of via structures in both of the x-axis and the y-axis. In some embodiments, as shown in FIG. 8, the set of interconnect structures (e.g., M5 810A, M4 820A, M3 830A, M2 840A, etc.) can be displaced from the other set (e.g., the BM0 506C, the M0 503C, etc.) of interconnect structures in both of the x-axis and the y-axis. In some embodiments, the circuit can include a plurality of rows (e.g., the row 801, the row 500R, etc.) arranged along the y-axis. As shown in FIG. 8, the row 801 can be displaced from the row 500R in both of the x-axis and the y-axis.

In some embodiments, the M2 track 840 can extend along the y-axis (e.g., shown as the M2 tracks 840A, 840B in FIG. 8). In some embodiments, the M2 track 840 can traverse the M1 track 530, the M3 track 830, etc. In some embodiments, the M3 track 830 can extend along the x-axis (e.g., shown as the M3 tracks 830A, 830B in FIG. 8). In some embodiments, the M3 track 830 can traverse the M2 track 840, the M4 track 820, etc. In some embodiments, the M4 track 820 can extend along the y-axis (e.g., shown as the M4 tracks 820A, 820B in FIG. 8). In some embodiments, the M4 track 820 can traverse the M1 track 530, the M3 track 830, etc. In some embodiments, the M5 track 810 can extend along the x-axis (e.g., shown as the M5 tracks 810A, 810B in FIG. 8). In some embodiments, the M5 track 810 can traverse the M4 track 820, the M2 track 840, the memory cells 825, 826, etc.

In some embodiments, the via structures (e.g., V1 805A, V2 804A, V3 803A, V4 802A, etc.) can extend along the z-axis to connect at least one of the M5 810, M4 820, M3 830, M2 840, etc. with another.

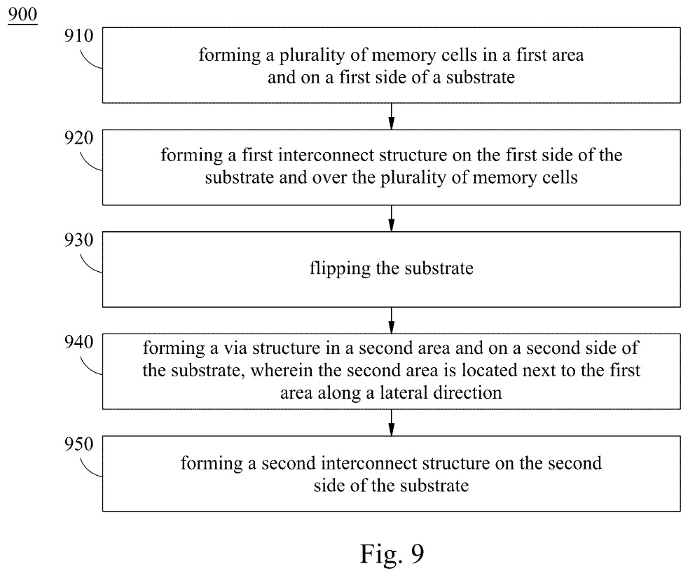

FIG. 9 illustrates a flow chart of an example method 900 for forming a memory device. In some embodiments, the method 900 can be performed to form a memory device based on the layouts discussed with respect to FIG. 3A, FIG. 3B, FIG. 5A, FIG. 5B, and FIG. 8, and thus, some of the references used above may be reused in the following discussion of the method 900. It is noted that the method 900 is merely an example and is not intended to limit the present disclosure. Accordingly, it is understood that additional operations may be provided before, during, and after the method 900 of FIG. 9, and that some other operations may only be briefly described herein.

In a brief overview, the method 900 can start with operation 910 of forming a plurality of memory cells in a first area and on a first side of a substrate. The method 900 can continue to operation 920 of forming a first interconnect structure on the first side of the substrate and over the plurality of memory cells. The method 900 can continue to operation 930 of flipping the substrate. The method 900 can continue to operation 940 of forming a via structure in a second area and on a second area of the substrate. The method 900 can continue to operation 950 of forming a second interconnect structure on the second side of the substrate.

At operation 910, a plurality of memory cells (e.g., the memory cells 225, 226) can be formed in a first area and on a first side (e.g., the frontside) of a substrate. In some embodiments, the plurality of memory cells can be formed such that the plurality of memory cells are arranged along a row and across a plurality of columns of a memory array. In some embodiments, the plurality of memory cells can include first memory cells and second memory cells arranged along a lateral direction. In some embodiments, the plurality of memory cells can include a static random access memory (SRAM) cell.

At operation 920, a first interconnect structure (e.g., the M1 track 330) can be formed on the first side of the substrate and over the plurality of memory cells. In some embodiments, the first interconnect structure can be coupled to respective gate terminals of the plurality of memory cells. For example, the first interconnect structure can be coupled to respective gate terminals of access transistors (e.g., the access transistor 225T) of the plurality of memory cells. At operation 930, the substrate can be flipped.

At operation 940, a via structure (e.g., the via structure 350) can be formed in a second area and on a second side (e.g., the backside) of the substrate. In some embodiments, the second area can be located next to the first area along a lateral direction. At operation 950, a second interconnect structure (e.g., the BM1 track 340) can be formed on the second side of the substrate. In some embodiments, the second interconnect structure can be coupled to the first interconnect structure through the via structure. In some embodiments, the first interconnect structure and the second interconnect structure each can extend along the lateral direction to traverse both the first and second areas. In some embodiments, the via structure can extend through the substrate to connect the first side to the second side of the substrate. In some embodiments, the via structure can be formed on the second side of the substrate.

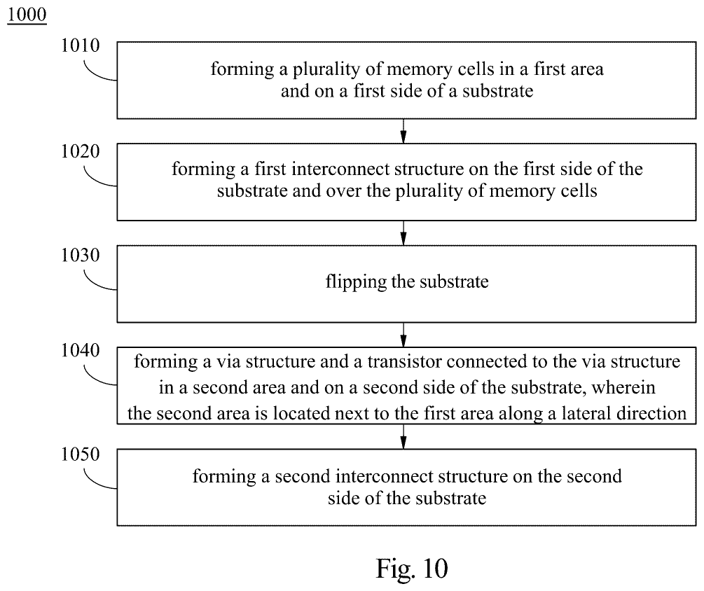

FIG. 10 illustrates a flow chart of an example method 1000 for forming a memory device. In some embodiments, the method 1000 can be performed to form a memory device based on the layouts discussed with respect to FIG. 3A, FIG. 3B, FIG. 5A, FIG. 5B, and FIG. 8, and thus, some of the references used above may be reused in the following discussion of the method 1000. It is noted that the method 1000 is merely an example and is not intended to limit the present disclosure. Accordingly, it is understood that additional operations may be provided before, during, and after the method 1000 of FIG. 10, and that some other operations may only be briefly described herein.

In a brief overview, the method 1000 can start with operation 1010 of forming a plurality of memory cells in a first area and on a first side of a substrate. The method 1000 can continue to operation 1020 of forming a first interconnect structure on the first side of the substrate and over the plurality of memory cells. The method 1000 can continue to operation 1030 of flipping the substrate. The method 1000 can continue to operation 1040 of forming a via structure and a transistor connected to the via structure in a second area and on a second area of the substrate. The method 1000 can continue to operation 1050 of forming a second interconnect structure on the second side of the substrate.

At operation 1010, a plurality of memory cells (e.g., the memory cells 425, 426) can be formed in a first area and on a first side (e.g., the frontside) of a substrate. In some embodiments, the plurality of memory cells can be formed such that the plurality of memory cells are arranged along a row and across a plurality of columns of a memory array. In some embodiments, the plurality of memory cells can include first memory cells and second memory cells arranged along a lateral direction. In some embodiments, the plurality of memory cells can include a static random access memory (SRAM) cell.

At operation 1020, a first interconnect structure (e.g., the M1 track 530) can be formed on the first side of the substrate and over the plurality of memory cells. In some embodiments, the first interconnect structure can be coupled to respective gate terminals of the plurality of memory cells. For example, the first interconnect structure can be coupled to respective gate terminals of access transistors (e.g., the access transistor 425T) of the plurality of memory cells. At operation 1030, the substrate can be flipped.

At operation 1040, a via structure (e.g., the via structure 560) and a transistor (e.g., the transistor 450) connected to the via structure can be formed in a second area and on a second side (e.g., the backside) of the substrate. In some embodiments, a gate terminal and a first source/drain terminal of the transistor can be coupled to the first interconnect structure, and a second source/drain terminal of the transistor can be coupled to the second interconnect structure through the via structure. In some embodiments, the transistor can be formed in a dissipation element (e.g., the dissipation element 550). For example, the dissipation element can be a dummy element to form the transistor therein. In some embodiments, the second area can be located next to the first area along a lateral direction. At operation 1050, a second interconnect structure (e.g., the BM1 track 540) can be formed on the second side of the substrate. In some embodiments, the second interconnect structure can be coupled to the first interconnect structure through the via structure. In some embodiments, the first interconnect structure and the second interconnect structure each can extend along the lateral direction to traverse both the first and second areas. In some embodiments, the via structure can extend through the substrate to connect the first side to the second side of the substrate. In some embodiments, the via structure can be formed on the second side of the substrate.

In one aspect of the present disclosure, a memory device is disclosed. The memory device includes a plurality of first memory cells formed in a first area of a substrate, a plurality of first via structures formed in a second area of the substrate, the second area being disposed next to the first area along a first lateral direction, a first one of a plurality of frontside interconnect structures formed on a first side of the substrate, wherein the first frontside interconnect structure is coupled to gate terminals of access transistors of the plurality of first memory cells, and a first one of a plurality of backside interconnect structures formed on a second side of the substrate vertically opposite to the first side, wherein the first backside interconnect structure is coupled to the first frontside interconnect structure through one or more of the plurality of first via structures.

In another aspect of the present disclosure, a memory device is disclosed. The memory device includes a memory array including a plurality of memory cells, wherein the plurality of memory cells are formed in a first area of a substrate, a first interconnect structure formed on a first side of the substrate, wherein the first interconnect structure operatively serves as a first portion of a word line for the plurality of memory cells, a second interconnect structure formed on a second side of the substrate opposite to the first side, wherein the second interconnect structure operatively serves as a second portion of the word line for the plurality of memory cells, and one or more via structures formed in a second area of the substrate next to the first area along a lateral direction, wherein the one or more via structures are configured to couple the first interconnect structure to the second interconnect structure, wherein the first interconnect structure and the second interconnect structure each extend along the lateral direction to traverse both the first and second areas.

In yet another aspect of the present disclosure, a method for forming a memory device is disclosed. The method includes forming a plurality of memory cells in a first area and on a first side of a substrate, forming a first interconnect structure on the first side of the substrate and over the plurality of memory cells, wherein the first interconnect structure are coupled to respective gate terminals of the plurality of memory cells, flipping the substrate, forming a via structure in a second area and on a second area of the substrate, wherein the second area is located next to the first area along a lateral direction, and forming a second interconnect structure on the second side of the substrate, wherein the second interconnect structure is coupled to the first interconnect structure through the via structure, wherein the first interconnect structure and the second interconnect structure each extend along the lateral direction to traverse both the first and second areas.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of first memory cells formed in a first area of a substrate;
a plurality of first via structures formed in a second area of the substrate, the second area being disposed next to the first area along a first lateral direction;
a first one of a plurality of frontside interconnect structures formed on a first side of the substrate, wherein the first frontside interconnect structure is coupled to gate terminals of access transistors of the plurality of first memory cells; and
a first one of a plurality of backside interconnect structures formed on a second side of the substrate vertically opposite to the first side, wherein the first backside interconnect structure is coupled to the first frontside interconnect structure through one or more of the plurality of first via structures.

2. The memory device of claim 1, wherein the first frontside interconnect structure and the first backside interconnect structure both extend along the first lateral direction.

3. The memory device of claim 1, further comprising:
a plurality of second memory cells formed in the first area of the substrate;
a plurality of second via structures formed in the second area of the substrate;
a second one of the plurality of frontside interconnect structures coupled to gate terminals of access transistors of the plurality of second memory cells; and
a second one of the plurality of backside interconnect structures coupled to the second frontside interconnect structure through one or more of the plurality of second via structures;
wherein the second frontside interconnect structure and the second backside interconnect structure both extend along the first lateral direction.

4. The memory device of claim 3, wherein each of the plurality of first memory cells and the plurality of second memory cells includes a static random access memory (SRAM) cell.

5. The memory device of claim 3, wherein the second memory cells are aligned with the first memory cells along a second lateral direction perpendicular to the first lateral direction, while the one or more first via structures are displaced from the one or more second via structures in both of the first and second lateral directions.

6. The memory device of claim 1, wherein the one or more first via structures each extend through the substrate.

7. The memory device of claim 6, further comprising:
a second one of the plurality of frontside interconnect structures, wherein the second frontside interconnect structure is vertically disposed between the substrate and the first frontside interconnect structure; and
a second one of the plurality of backside interconnect structures, wherein the second backside interconnect structure is vertically disposed between the substrate and the first backside interconnect structure.

8. The memory device of claim 7, wherein the one or more first via structures are each in direct contact with the second frontside interconnect structure and the second backside interconnect structure.

9. The memory device of claim 7, wherein the first interconnect structure, the second frontside interconnect structure, and the first backside interconnect structure each extend in the first lateral direction, while the second backside interconnect structure extends in a second lateral direction perpendicular to the first lateral direction.

10. The memory device of claim 1, wherein the first frontside interconnect structure and the first backside interconnect structure operatively serve as a portion of a word line of the first memory cells.

11. The memory device of claim 1, wherein the first memory cells are configured to be arranged along a row and across a plurality of columns of a memory array, and wherein the memory array is formed in the first area.

12. A memory device, comprising:
a memory array comprising a plurality of memory cells, wherein the plurality of memory cells are formed in a first area of a substrate;
a first interconnect structure formed on a first side of the substrate, wherein the first interconnect structure operatively serves as a first portion of a word line for the plurality of memory cells;
a second interconnect structure formed on a second side of the substrate opposite to the first side, wherein the second interconnect structure operatively serves as a second portion of the word line for the plurality of memory cells; and
one or more via structures formed in a second area of the substrate next to the first area along a lateral direction, wherein the one or more via structures are configured to couple the first interconnect structure to the second interconnect structure;
wherein the first interconnect structure and the second interconnect structure each extend along the lateral direction to traverse both the first and second areas.

13. The memory device of claim 12, wherein the one or more via structures each extend through the substrate to connect the first side to the second side of the substrate.

14. The memory device of claim 12, wherein the one or more via structures are each formed on the second side of the substrate.

15. The memory device of claim 14, further comprising:
at least one transistor formed in the second area of the substrate;
wherein a gate terminal and a first source/drain terminal of the at least one transistor is coupled to the first interconnect structure, and a second source/drain terminal of the at least one transistor is coupled to the second interconnect structure through the one or more via structures.

16. The memory device of claim 12, wherein each of the plurality of memory cells includes a static random access memory (SRAM) cell.

17. The memory device of claim 12, wherein the first interconnect structure and the second interconnect structure are each coupled to respective gate terminals of the plurality of memory cells.

18. A method for forming a memory device, comprising:
forming a plurality of memory cells in a first area and on a first side of a substrate;
forming a first interconnect structure on the first side of the substrate and over the plurality of memory cells, wherein the first interconnect structure are coupled to respective gate terminals of the plurality of memory cells;
flipping the substrate;
forming a via structure in a second area and on a second side of the substrate, wherein the second area is located next to the first area along a lateral direction; and
forming a second interconnect structure on the second side of the substrate, wherein the second interconnect structure is coupled to the first interconnect structure through the via structure;
wherein the first interconnect structure and the second interconnect structure each extend along the lateral direction to traverse both the first and second areas.

19. The method of claim 18, wherein the via structure extends through the substrate to connect the first side to the second side of the substrate.

20. The method of claim 18, wherein the via structure is formed on the second side of the substrate.
